(19) United States
(12) Patent Application Publication
(10) Pub. No.: US 2013/0141136 A1
(43) Pub. Date: Jun. 6, 2013

(54) METHOD AND APPARATUS FOR PARASITIC CURRENT DETECTION

(71) Applicant: Phoenix Contact GmbH & Co. KG, Blomberg (DE)

(72) Inventor: Gerhard Wolff, Extertal (DE)

(73) Assignee: Phoenix Contact GmbH & Co. KG, Blomberg (DE)

(21) Appl. No.: 13/758,161

(22) Filed: Feb. 4, 2013

Related U.S. Application Data
(63) Continuation of application No. PCT/EP2011/063381, filed on Aug. 3, 2011.

(30) Foreign Application Priority Data
Aug. 4, 2010 (DE) 10 2010 036 847.4

(51) Int. Cl. G01R 31/40

(52) U.S. Cl. CPC G01R 31/40
USPC 324/764.01

(57) ABSTRACT

The invention relates to a method for parasitic current detection in a power supply system, which comprises at least one electrical unit, a power grid having power paths for supplying the unit, and a central electrical feed apparatus for feeding electrical power into the power grid, wherein the feed apparatus is connected to a first of the power paths, at which a reference potential is present, and is connected to at least a second of the power paths, at which a potential for generating an operating current through the unit is present, wherein the first power path is earthed by means of a defined first earthing branch of a connecting portion of the first power path, said connecting portion being connected directly to the feed apparatus and being otherwise unbranched. The invention further relates to an apparatus for carrying out the method.

### CROSS-REFERENCE TO RELATED APPLICATIONS

This application is a continuation of International Application No. PCT/EP2011/063381, filed Aug. 3, 2011, which claims the benefit of German Application No. 10 2010 036 847.4 filed Aug. 4, 2010, the entire disclosures of which are hereby incorporated by reference.

### FIELD

The invention relates to a method for parasitic current detection in a power supply system, which comprises at least one electrical unit, a power grid having power paths for supplying the unit, and a central electrical feed apparatus for feeding electrical power into the power grid, wherein the feed apparatus is connected to a first of the power paths, at which a reference potential is present, and is connected to at least a second of the power paths, at which a potential for generating an operating current through the unit is present, wherein the first power path is earthed by means of a defined first earthing branch of a connecting portion of the first power path, said connecting portion being connected directly to the feed apparatus and being otherwise unbranched. The invention further relates to an apparatus for carrying out the method.

### BACKGROUND

Power supply systems, of which the reference potential is connected once to earth, are used in different fields of application. For example, 24-volt DC systems with positive potential for generating an operating current and earthed negative potential as a reference potential are widespread. Furthermore, 230-volt AC systems for example are known, in which the reference potential present at the neutral conductor (neutral conductor potential) is earthed at least at one point (TN or TT systems).

In applications of direct voltage supplies of any type that are operated with earthed reference potential (for example negative potential), it has been found that multiple earthings of the reference potential may cause inadmissible influences and operational disruptions, and may even result in the units or the feed apparatus connected to these systems being destroyed. As a result of these multiple earthings, parasitic direct currents or alternating currents of any frequency (parasitic currents for short) can infiltrate the power supply system in a line-conducted manner (galvanically) and can interfere with the operating parameters. Power supply systems of this type do not generally have monitoring mechanisms that reveal critical multiple earthings at the moment of production. Multiple earthings of the reference potential therefore initially remain undiscovered in most cases.

Previously, system solutions for detecting parasitic currents that monitor the defined earthing branch of the first power path for a flow of the earth fault current have been known. These monitoring devices ideally detect direct and/or alternating currents and are thus AC/DC-sensitive.

If, due to additional earth connections of the reference potential already earthed via the earthing branch, currents flow through the earth connections and the first power path or are produced in a superposed manner by the unearthed potential for generating operating current, for example as a result of potential differences in the earthed potential equalisation system of the plant or by starting up the feed apparatus itself, the previously mentioned monitoring device detects this current.

However, this detection method has the disadvantage that unavoidable superposed alternating currents occurring in practice and produced for example by EMC filters and by the natural inherent capacitance of line systems and devices, such as the electrical unit and the feed apparatus, may lead to false signalling. An earth fault of the potential, which is unearthed under normal operating conditions, for generating the operating current may also lead in this case to false signalling.

### SUMMARY

The object of the invention is therefore to provide a method for detecting parasitic current and an apparatus for carrying out this method, which can distinguish between signals produced by superposed alternating currents and parasitic currents (system parasitic currents).

The object is achieved in accordance with the invention by the features in claims 1 and 8. Advantageous embodiments of the invention are disclosed in the dependent claims.

With the method according to the invention for detecting parasitic currents in a power supply system, the parasitic current (system parasitic current) is established by comparing the operating current with an earth fault current flowing through the earthing branch. To this end, the earth fault current flowing through the earthing branch is determined and the operating current in the second power path is established by current measurement. These two processes of determining the earth fault current and establishing the operating current are carried out dynamically, that is to say as continuous or practically continuous processes. The dynamics are preferably characterised by a frequency range from 0 Hz to approximately 1 kHz.

The method enables a practical solution, which “blends out” (parasitic) currents capacitively coupled into or out from the reference potential of the power supply system and forms a dynamic command quantity, according to momentary values of the operating current of the supply system, for a comparison with the earth fault current flowing through the earthing branch, that is to say in the line between reference potential and earth.

In accordance with an advantageous embodiment of the invention, the operating current (load current) of the power supply system is established by measuring current at least at one connecting portion of the second power path, said connecting portion being connected directly to the feed apparatus and being otherwise unbranched. This measure ensures that the entire operating current, that is to say a total current flowing through electrical units, is measured, since the feed apparatus is a central feed apparatus of the power grid.

In accordance with a further advantageous embodiment of the invention, a first quantity proportional to the earth fault current and a second quantity proportional to the established operating current are determined for the comparison, and the comparison is made by establishing the difference between these two quantities. In particular, the two quantities are voltage quantities. In this case the output quantity of a sensor for determining the earth fault current flowing through the earthing branch is a voltage value proportional to the actual value of the operating current, and the output quantity of an apparatus for establishing the operating current is a voltage value proportional to the operating current. Both voltage values are converted, in particular by means of assigned voltage dividers, into quantities that can be compared with one another.

In particular, the comparison is carried out by means of a comparator circuit comprising a comparator. The comparator circuit preferably also comprises the voltage dividers. The outputs of the two voltage dividers are guided to the inputs of the comparator. To detect parasitic current, the comparator determines the difference between the corresponding quantities. The voltage value proportion to the operating current is a dynamic command quantity, and the voltage value proportional to the earth fault current is a value that is compared with these dynamic command quantities.

In accordance with an advantageous embodiment of the invention, a comparison result exceeding a threshold value triggers a signal output and/or a safety measure of the power supply system. In this case, a plurality of threshold values are provided in particular. For example, at a first threshold value, at which the deviation (difference) is small, a signal: “attention advised” is output. Reasons for a deviation of this type include, for example, excessively high leakage currents and/or creeping low resistance. If a further, higher threshold value is exceeded, the notification: “attention required” is output. If a further threshold value of this type is exceeded, multiple earthing is to be assumed. If threshold values that are higher still are exceeded, the system may thus be disconnected completely or in part for example. Reasons for this for example may be a short circuit (high DC portion) or an excessively low parasitic current portion.

In accordance with a further advantageous embodiment of the invention, the power supply system is a direct voltage system, in which the potential difference between the potential for generating the current flow and its reference potential is substantially constant. The expression “substantially constant” allows fluctuations in voltage caused by load that may always be present in such systems. In particular, in the case of the direct voltage system, the feed apparatus is a converter or comprises a converter.

In accordance with an alternative embodiment of the invention, the power supply system is an alternating voltage system, in which the reference potential is a neutral conductor potential, in particular an earthed neutral conductor potential (TN or TT system), and the at least one potential for generating the current flow is a phase potential varying periodically around the reference potential. The alternating voltage system may be a single-phase alternating voltage system or a multi-phase alternating voltage system in this case. A typical multi-phase alternating voltage system is a three-phase system. In particular, in the case of alternating voltage systems, the feed apparatus is a transformer or comprises a transformer.

The apparatus according to the invention for carrying out the above-described method comprises: (a) an AC/DC-sensitive sensor for determining the earth fault current flowing through the earthing branch, (b) a device for measuring current at the at least one connecting portion of the second power path and for establishing therefrom the operating current, and (c) a comparator circuit comprising a device for determining the first quantity proportional to the earth fault current and the second quantity proportional to the established operating current, and comprising a comparator for comparing the two quantities. The detection of the actual value of the current carried out by the sensor and/or the device for current measurement is AC/DC-sensitive, that is to say is sensitive to direct and alternating current portions. The comparator circuit is preferably formed in a microcontroller (μC), which also comprises modules for signal preparation and signal evaluation.

In accordance with an advantageous embodiment of the invention, the device comprises two voltage dividers, of which the outputs are connected to inputs of the comparator so that signals can be transmitted. The comparator circuit thus comprises two voltage dividers connected upstream of the comparator, which are preferably electronically programmable. They are optionally formed by means of a potentiometer/DIP switch,

With more than one second power path, further voltage dividers are necessary. The signals of said voltage dividers are to be prepared suitably, depending on the type of system, and then fed to the comparator.

In accordance with a preferred embodiment of the invention the apparatus comprises an evaluation unit for evaluating the comparison quantity by comparing it with a predefinable threshold value. The evaluation unit outputs a signal, for example to a signal output device, if the comparison quantity exceeds the threshold value.

In accordance with a further advantageous embodiment of the invention, the apparatus is suitable for detection in a dynamic range from 0 Hz to at least 2 kHz, preferably front 0 Hz to at least 20 kHz. Parasitic currents are produced typically in this frequency spectrum by the capacitive earthings.

Lastly, the apparatus is not only suitable in general, but advantageously is also adapted specifically to carry out the above-described method. The AC/DC-sensitive sensor is adapted to determine the earth fault current flowing through the earthing branch. The device for measuring current is adapted to measure current at the at least one further connecting portion of the second power path and to establish the operating current therefrom. The device in the comparator circuit is adapted to determine the first quantity proportional to the earth fault current and the second quantity proportional to the established operating current, and the comparator in the comparator circuit is adapted to compare the two quantities.

The invention lastly also relates to a feed and parasitic current detection apparatus, which comprises the feed apparatus and the above-described apparatus for carrying out said method for parasitic current detection. The feed apparatus and the apparatus for parasitic current detection are in particular arranged in a common housing of the feed and parasitic current detection apparatus.

### BRIEF DESCRIPTION OF THE DRAWINGS

The invention will be explained in greater detail hereinafter with reference to the accompanying drawings and on the basis of preferred embodiments.

In the drawings:

FIG. 1 shows a power supply system comprising an electrical feed apparatus for feeding power and comprising a power grid having a first and a second power path, wherein a reference potential that is earthed is present at the first power path,

FIG. 2 shows the power supply system of FIG. 1 with a reference potential earthed capacitively a number of times, and

FIG. 3 shows the power supply system of FIG. 1 with an apparatus for parasitic current detection in the power supply system.

### DESCRIPTION OF PREFERRED EMBODIMENTS

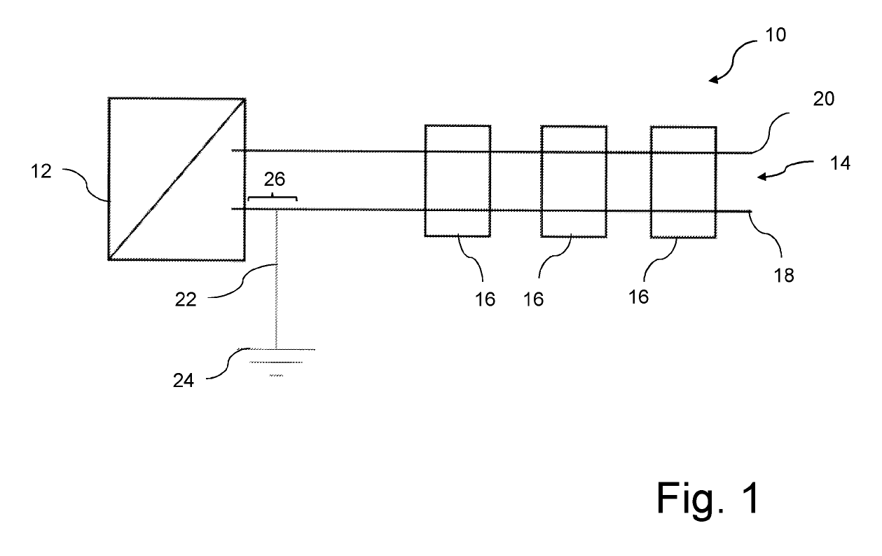

FIG. 1 shows a power supply system 10 comprising a central electrical feed apparatus 12 for feeding electrical power into a power grid 14 of the power supply system 10. A plurality of electrical units 16 are connected in the power grid 14 and are supplied with power by the feed apparatus 12. The power grid 14 is formed as a DC power grid 14 and comprises two power paths 18, 20. A reference potential φ1 formed as a negative potential (“minus potential”) is present at the first power path 18, and a potential φ2 (“plus potential”) that is greater than the reference potential φ1 is present at the second line path 20 to generate an operating current through the power grid 14. The potential difference (Δφ=φ2−φ1) between the two potentials φ1, φ2 is constant. The power grid 14 is thus a power grid supplied by a constant voltage. The first power path 18 having the reference potential φ1 is connected by means of a defined earthing branch 22 at a point 24 to earth potential. The earthing branch 22 is part of a connecting portion 26 of the first power path 18, said connecting portion being otherwise unbranched.

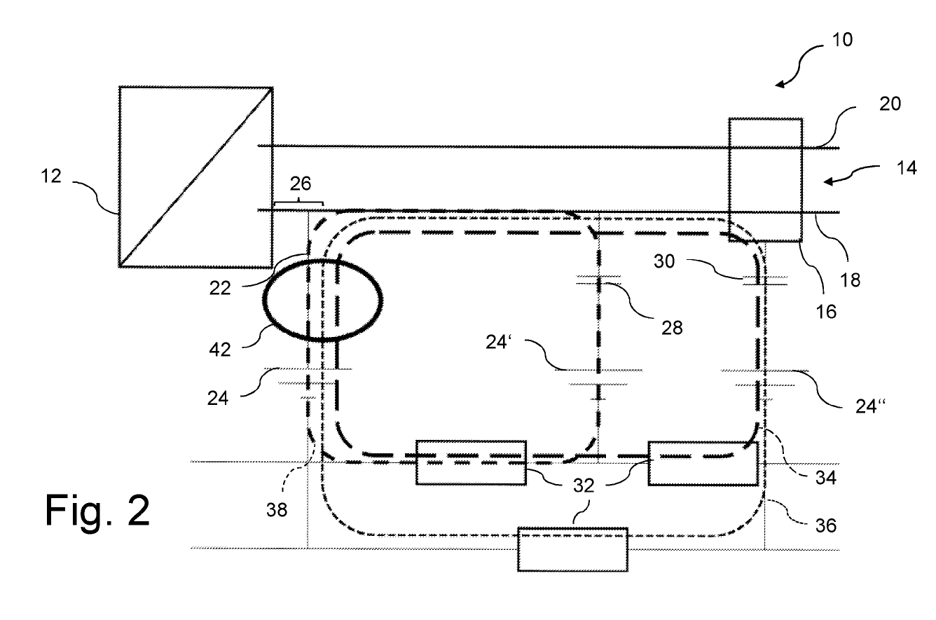

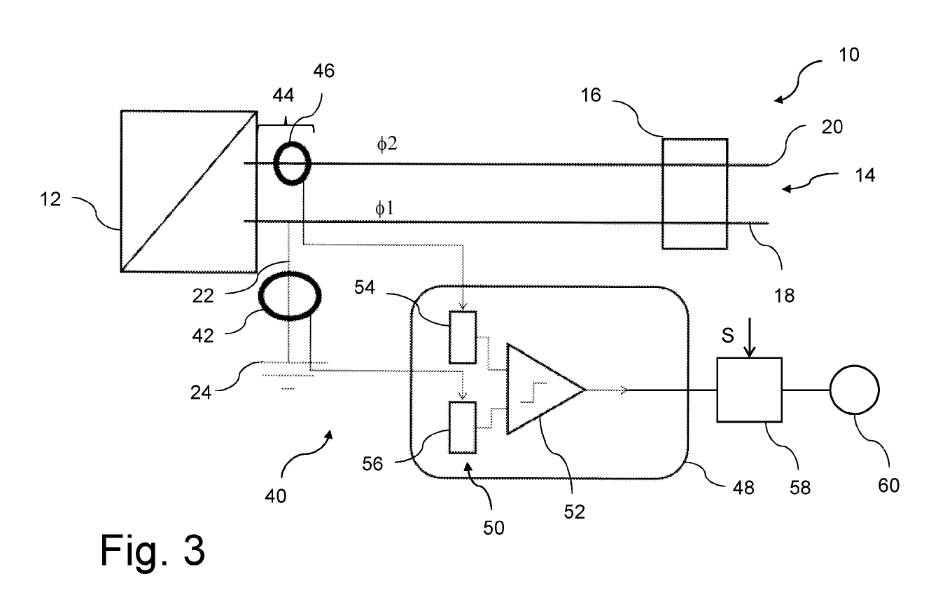

FIG. 2 shows the power supply system 10 in a region of the feed apparatus 12 as far as a first unit. In this case, the first line path 18 is not only connected to the reference potential φ1 via the defined earthing branch 22, but is also connected capacitively via a line capacitor 28 to earth potential at another point 24′ and is connected via a unit capacitor 30 to earth potential at a further point 24″. The different points of the earth potential 24, 24′, 24″ are in turn electrically interconnected via (specific) earth resistors 32, so that three para current circuits 34, 36, 38, or what are known as earth loops, are produced. Each of these parasitic current circuits 34, 36, 38 passes the earthing branch 22 in this case. By determining the earth fault current flowing through the earthing branch 22, it is thus possible to determine the total current of the parasitic current circuits 34, 36, 38. An apparatus 40 for parasitic current detection shown in FIG. 3 comprises a corresponding sensor 42 for this purpose.

FIG. 3 then shows the same portion of the power supply system 10 as in FIG. 2, wherein the apparatus for parasitic current detection is shown instead of the parasitic current circuits 34, 36, 38. In addition to the sensor 42 for determining the earth fault current flowing through the earthing branch 22, the apparatus 40 exhibits a device for measuring current and establishing the operating current 46 at a further unbranched connecting portion 44. The apparatus 40 further has a comparator circuit 48 comprising a device 50 for determining a first quantity V1 proportional to the earth fault current and a second quantity V2 proportional to the operating current, and comprising a comparator 52. The device 50 comprises two voltage dividers 54, 56 to match the two quantities.

By means of the apparatus 40, the parasitic current is then established by a dynamic comparison of the operating current with an earth fault current flowing through the earthing branch 22. To this end, the first quantity V1 proportional to the earth fault current is determined by means of the sensor 42 and the quantity V2 proportional to the established operating current is determined by means of the device 46 for measuring current, both quantities V1, V2 are matched to one another by means of the device 50 and are compared with one another by means of the comparator 52 by subtraction. The invention 50 in this case comprises two voltage dividers 54, 56 for matching the quantities V1, V2 formed as voltage quantities. The result of the comparison is then in turn compared with a threshold value S by means of an evaluation unit 58. This is connected to a signal output 60 and is wired thereto such that said signal output outputs a signal if the result of the comparison exceeds the threshold value S. This signal for example indicates that multiple earthings are to be assumed within the power supply system 10.

The following advantages are achieved: The method according to the invention describes a practical solution for “blending out” the currents capacitively coupled into or out from the line of the power supply system 10 with the reference potential φ2. To this end, a dynamic command quantity is formed, depending on the momentary value of the operating current (actual value of the operating current), for the evaluation unit 58 of the current detection in the earthing branch. This command quantity is compared in the evaluation unit 58 with individually predefinable relative threshold values. If this threshold value is reached and/or exceeded, the signal output 60 is prompted to emit signals. Earth fault currents may optionally he blended out or additionally detected. With such a solution it is possible to allow permissible leakage current towards the earth potential in the correctly functioning, normal operating state of the power supply system due to system-dependent capacitors 28, 30 present in this power supply system 10, but to identify capacitive currents deviating upwardly from this value and to trigger corresponding signal outputs once threshold values have been reached or exceeded.

On the one hand, ohmic coatings between system earth (reference potential φ2) and earth potential are thus identified, and on the other hand capacitive fault currents dependent on the load current of the system care also identified. This combination leads to the identification of multiple earthings or creeping insulation resistance reduction, without accidental signal output triggered by system-dependent capacitive leakage currents.

The maximum permissible quantity, known in the heavy current field, of leakage currents caused by EMC filters is 1 mA per kW. A total leakage current with 0.5 to 1% of the operating current is normally assumed by practitioners in the field of EMC plants to be representative of this.

If the momentary operating current of a power supply system 10 is taken as a base value and from this a relative threshold value is derived, for example 1% or 2%, this threshold value is dynamically adapted in accordance with the operating current. Complex reactions of load changes in terms of their effects on leakage currents are thus detected “slidingly”. Only actual changes to the insulation state form the basis of a signal output. Leakage currents caused by filters are thus blended out. Only currents flowing via insulation reduction are evaluated for this purpose.

By contrast to the heavy current field, preventative fire protection (300 mA) or protection against electric shock (30 mA) are not significant criteria, but the risk of endangerment, undetected under normal operating conditions, caused by effects of coupled-in parasitic currents in the DC frequency range to the lower MHz range (destruction of hardware and signal falsification cause by superposed voltages that could lead to maloperation).

The method can be applied both to existing plants and to new plants. In the case of application in existing plants, the apparatus 40 is to be introduced into the system circuitry of the power supply system 10, and the evaluation unit 54 can be arranged separately therefrom. The same applies to application in new plants.

### LIST OF REFERENCE SIGNS

power supply system 10

feed apparatus

power grid 14

electrical unit 16

first power path 18

second power path 20

earthing branch

point with earth potential 24, 24′, 24″

connecting portion 26

line capacitor 28

unit capacitor 30

earth resistor 32

parasitic current circuit 34

parasitic current circuit 36

parasitic current circuit 38

apparatus for parasitic current detection

sensor 40

further connecting portion 42

device 44

comparator circuit 46

device 48

comparator 50

voltage divider 52

voltage divider 54

evaluation unit 56

signal output 58

60

1. A method for parasitic current detection in a power supply system, the power supply system comprising:
at least one electrical unit;
a power grid having at least two power paths for supplying the electrical unit; and
a central electrical feed apparatus for feeding electrical power into the power grid;
wherein the feed apparatus is connected to a first one of the power paths, at which a reference potential is present, the feed apparatus being further connected to at least a second of the power paths, at which a potential for generating an operating current through the unit is present;
wherein the first power path is earthed by means of a defined first earthing branch of a first connecting portion of the first power path, said first connecting portion being connected directly to the feed apparatus and being otherwise unbranched, characterised in that the parasitic current is established by comparing the operating current with an earth fault current flowing through the earthing branch.

2. The method according to claim 1, wherein the operating current is established by measuring current at least at a second connecting portion of the second power path, said second connecting portion being connected directly to the feed apparatus and being otherwise unbranched.

3. The method according to claim 1, wherein a first quantity proportional to the earth fault current and a second quantity proportional to the established operating current are determined for the comparison, and the comparison is made by establishing the difference between these two quantities.

4. The method according to claim 1, wherein the comparison is carried out by means of a comparator circuit comprising a comparator.

5. The method according to claim 1, wherein a comparison result exceeding a threshold value triggers a signal output or a safety measure of the power supply system.

6. The method according to claim 1, wherein the power supply system is a direct voltage system, in which the potential difference between the potential for generating the current flow and the reference potential is substantially constant.

7. The method according to claim 1, wherein the power supply system is an alternating voltage system, in which the reference potential is a neutral conductor potential and the at least one potential for generating the current flow is a phase potential varying periodically around the reference potential.

8. An apparatus for carrying out the method according to claim 1, comprising:
an AC/DC-sensitive sensor for determining the earth fault current flowing through the earthing branch;
a first device for measuring current at a second connecting portion of the second power path and for establishing therefrom. the operating current; and
a comparator circuit comprising a second device for determining a first quantity proportional to the earth fault current and a second quantity proportional to the established operating current, the comparator circuit further comprising a comparator for comparing the first and second quantities.

9. The apparatus according to claim 8, wherein the second device comprises two voltage dividers, of which the outputs are connected to inputs of the comparator so that signals can be transmitted.

10. The apparatus according to claim 8, comprising an evaluation unit for evaluating the comparison quantity by comparing the comparison quantity with a predefinable threshold value.

11. The apparatus according to claim 8, wherein the apparatus is suitable for detection in a dynamic range from 0 Hz to at least 2 kHz.

12. The apparatus according to claim 8, wherein the apparatus is adapted to carry out the method according to claim 8.

13. A feed and parasitic current detection apparatus, which comprises the central electrical feed apparatus and the apparatus for parasitic current detection according to claim 8.
